(19) United States
(12) Patent Application Publication
(10) Pub. No.: US 2011/0247556 A1
(43) Pub. Date: Oct. 13, 2011

(54) Tapered Horizontal Growth Chamber

(75) Inventors: James W. Raring, Goleta, CA (US); Arpan Chakraborty, Goleta, CA (US); Mike Coulter, Goleta, CA (US)

(73) Assignee: Soraa, Inc., Goleta, CA (US)

(21) Appl. No.: 13/046,565

(22) Filed: Mar. 11, 2011

Related U.S. Application Data
(60) Provisional application No. 61/319,765, filed on Mar. 31, 2010.

(51) Int. Cl. C23C 16/455; C23C 16/458

(52) U.S. Cl. 118/713; 118/715; 118/725

(57) ABSTRACT

A system and techniques for performing deposition having a tapered horizontal growth chamber which includes a susceptor and a tapered channel flow block. A tapered chamber is formed between the susceptor and the tapered channel flow block. Gaseous species introduced are forced by the tapered channel block to flow toward the susceptor to enhance the efficiency of reactions between the gases species and a wafer on the susceptor.

### CROSS-REFERENCE TO RELATED APPLICATION

The present application claims priority from U.S. Patent Application No. 61/319,765, filed Mar. 31, 2010, entitled “Tapered Horizontal Growth Chamber,” commonly assigned and incorporated by reference hereby for all purposes.

### BACKGROUND OF THE INVENTION

This invention is related to a system and techniques to perform deposition. More specifically, embodiments of the invention provide a tapered horizontal growth chamber which allows for efficient growth and reaction of semiconductor substrates and/or wafers placed in the chamber. In a specific embodiment, the horizontal growth chamber includes a susceptor and a tapered channel flow block. A tapered chamber is formed between the susceptor and the tapered channel flow block. A nozzle, which can be multiple-channeled, is positioned at the wide end of the tapered chamber to introduce gases species that flows toward the narrow end of the tapered chamber. Gaseous species introduced by the nozzle are forced by the tapered channel block to flow toward the susceptor, thereby making possible efficient reactions between the gases species and the wafer on the susceptor.

Over the past decades, many systems and techniques have been developed for manufacturing various types of semiconductor devices, ranging from computer chips to LEDs. Various equipment, such as etching tools, polishing machines, and deposition chambers, are widely used. One useful tool for forming certain types of LED devices is an epitaxial growth reactor configuration designed to achieve high precursor consumption efficiency. Over the past, various types of conventional reactors have been used. Unfortunately, these conventional tools are inadequate for various reasons.

### BRIEF SUMMARY OF THE INVENTION

The invention is related to a system and techniques for performing deposition. More specifically, embodiments of the invention provide a tapered horizontal growth chamber which allows for efficient growth and reaction of semiconductor substrates and/or wafers placed the chamber. In a specific embodiment, the horizontal growth chamber includes a susceptor and a tapered channel flow block. A tapered chamber is formed between the susceptor and the tapered channel flow block. A nozzle, which can be multiple-channeled, is positioned at the wide end of the tapered chamber to introduce gases species that flows toward the narrow end of the tapered chamber. Gaseous species introduced by the nozzle are forced by the tapered channel block to flow toward the susceptor, thereby making possible efficient reactions between the gases species and the wafer on the susceptor.

According to one embodiment, the invention provides an MOCVD apparatus. The apparatus includes an inlet region, an outlet region, and a susceptor region between the inlet region and the outlet region. A tapered flow region has a first dimension at the inlet region and a second dimension at the outlet region.

The invention also provides an apparatus for epitaxial growth which includes a reactor housing and a susceptor having a holding surface for wafers. A tapered flow block faces the holding surface. A chamber between the holding surface and the tapered surface has a first height at a first end and a second height at a second end, the first height being different from the second height by at least 20%. A nozzle introduces gaseous species into the chamber, and a heating module is thermally coupled to the susceptor. In some embodiments, the apparatus includes a showerhead assembly integrated within the tapered flow block.

The invention provides an epitaxial growth reactor which achieves high precursor consumption efficiency, high epitaxial film quality, and high growth uniformity across large area wafers, e.g. from 2″ to 8″ and larger. The tapered flow channel design allows for increased precursor utilization and uniformity. In addition, the vertically stacked multi-channel flow nozzle increases growth efficiency by forcing the precursors towards the wafer, and enabling selective positioning the various precursors relative to the wafer. One application for the tapered reactor chamber is deposition of indium for incorporation in InGaN films.

### BRIEF DESCRIPTION OF THE DRAWINGS

FIG. 1 is a diagram illustrating a taper chamber;

FIG. 2 is a diagram illustrating an inverted tapered chamber;

FIGS. 3 and 4 are schematic diagrams of single wafer reactors and multi-wafer reactors;

FIGS. 5 and 6 are diagrams illustrating tapered growth chambers with two-flow assemblies;

FIG. 7 is a top view of a showerhead a shower head with circuit flow channels;

FIG. 8 is a top view of a showerhead a shower head with rectangular flow channels; and

FIGS. 9-12 are diagrams illustrating showerhead having tubes at different angles.

### DETAILED DESCRIPTION OF THE INVENTION

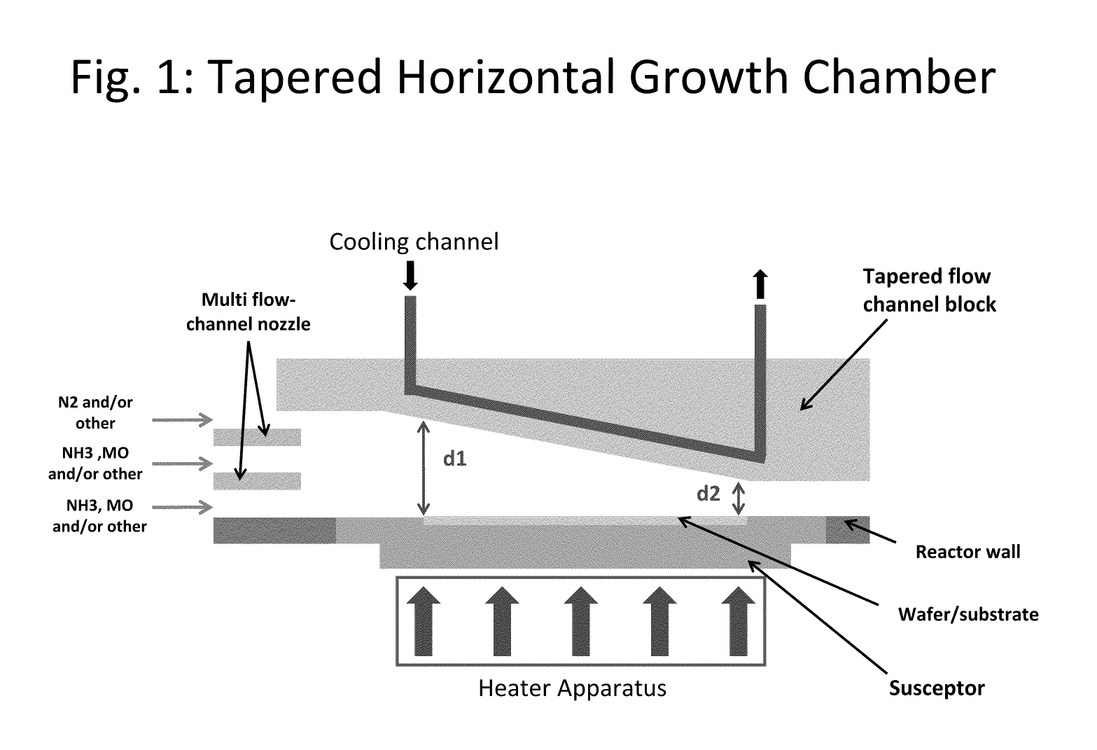

Embodiments of the invention provide reactors with tapered chambers. FIG. 1 is a diagram illustrating a tapered chamber according to an embodiment of the invention. As shown in FIG. 1, the tapered horizontal growth chamber includes a tapered flow block. A copper metal tapered flow block is preferable for efficient thermal conductivity, however, graphite can also be used. The metal flow block reduces the amount of deposition on the inside of the chamber. In various embodiments, the tapered flow block includes cooling channels which allow coolant (e.g., water) to remove heat from the tapered flow block as the coolant flows through the cooling channel. Good thermal conductivity of the tapered horizontal growths chamber makes removing heat by coolant efficient. Having the wafer and/or substrate placed on the susceptor as shown in FIG. 1, constrains motion of the wafer, making wafer breakage rare. In the case of wafer breakage or debris breaking free from the wafer or susceptor, the debris would remain on, or fall onto, the wafer where it is removed with the wafer and susceptor when the growth was completed.

The tapered flow channel restricts the boundary layer along the direction of gas flow. By restricting the boundary layer close to the substrate surface (0.2 to 10 mm) the precursor utilization efficiency can be large enabling high growth rates at temperatures (700-1300 C) required for GaN-based epitaxy. Further, by compensating for the precursor depletion in the direction of the gas flow with a boundary layer thickness that is reduced along the length of the flow direction, the uniformity of the epitaxial growth rate, and hence the resulting thickness uniformity, can be greatly improved.

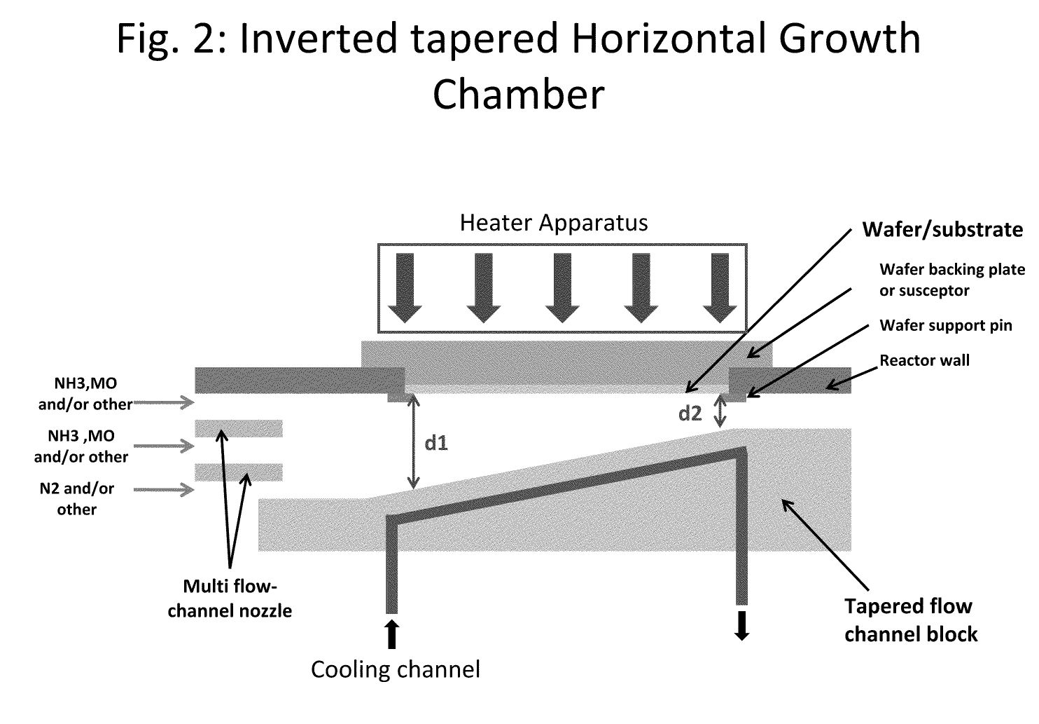

This horizontal chamber design can be configured in a manner as shown in FIG. 1 where the wafer/substrate is placed on a susceptor and constrained vertically by gravity and constrained laterally by physical surfaces or other means. In another embodiment, the chamber could be inverted where the growth surface of the wafer/substrate faces downward. FIG. 2 is a diagram illustrating an inverted tapered chamber. The inverted requires mechanical pins, a mechanical surface, a vacuum stage, or other means to constrain the wafer vertically and laterally.

As illustrated in FIGS. 1 and 2, the tapered flow channel block is positioned above the wafer in a non-inverted design or below the wafer in an inverted design. The design of this component as the distance it is positioned away from the wafer along the direction of flow dictates the shape of the boundary layer. As shown in FIGS. 1 and 2, linear tapers are employed where the distance the flow channel block is positioned away from the growth surface varies linearly with distances along the flow direction. The angle of the taper and the distance of the block from the growth surface can be specified with two dimensions; “d1” the distance from the wafer growth surface to the flow channel block at the leading edge of the wafer, and “d2” the distance from the wafer growth surface to the flow channel block at the second edge of the wafer. The most typical or desired embodiment has d1>d2, where d1 ranges from 2-20 mm and d2 ranges from 0.5-5 mm. The taper profile could also use a non-linear profile, for example, exponential or parabolic.

The tapered flow channel block is preferably cooled. In various embodiments, the invention provides methods such as creating a coolant channel in the block and flowing a medium such as water through the channel to extract the heat. By cooling the flow channel block, deposition on the block can be minimized such that the chamber can provide more hours of operation between cleanings Further, by cooling the block the thermal gradient that extends from the growth surface of the wafer/substrate towards the flow channel block can be maximized to mitigate convection and conduction assisted expansion of the boundary layer.

An aspect of the tapered flow channel block is heat dissipation. Different materials could be used, including metals and ceramics. In our preferred embodiment, we use a metal flow channel block. The metal is preferably copper, alloyed copper, stainless steel, or aluminum. The copper block can be constructed using graphite, SiC coated graphite, SiC, pyrolytic boron nitride (PBN), or other materials.

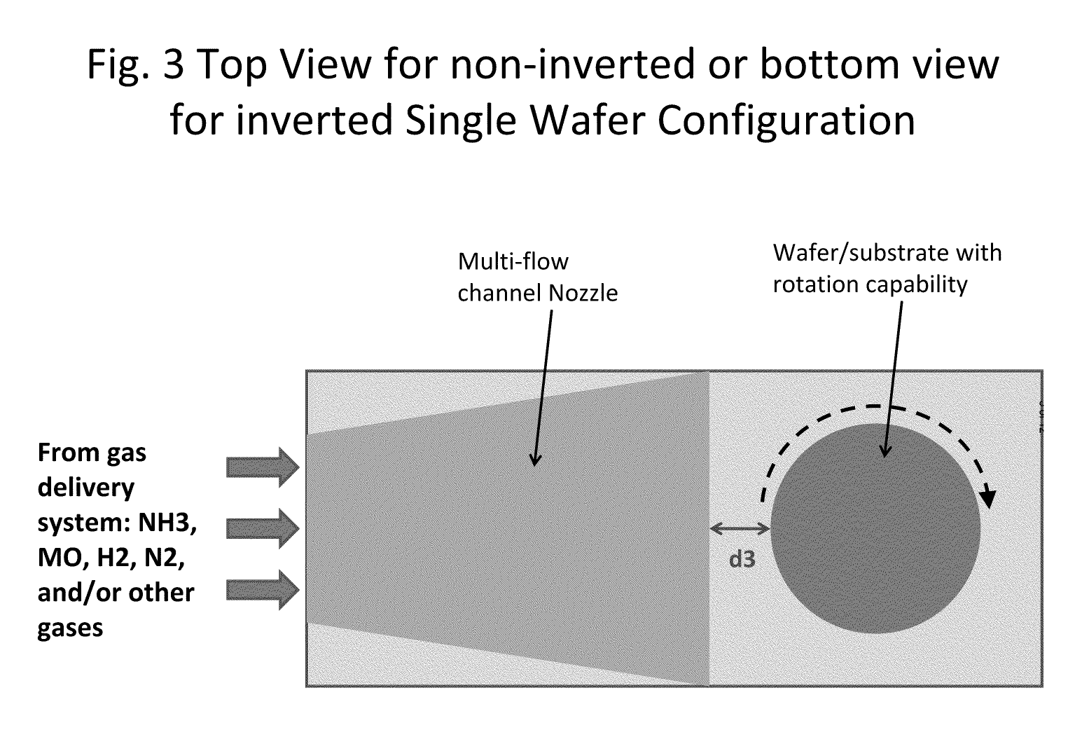

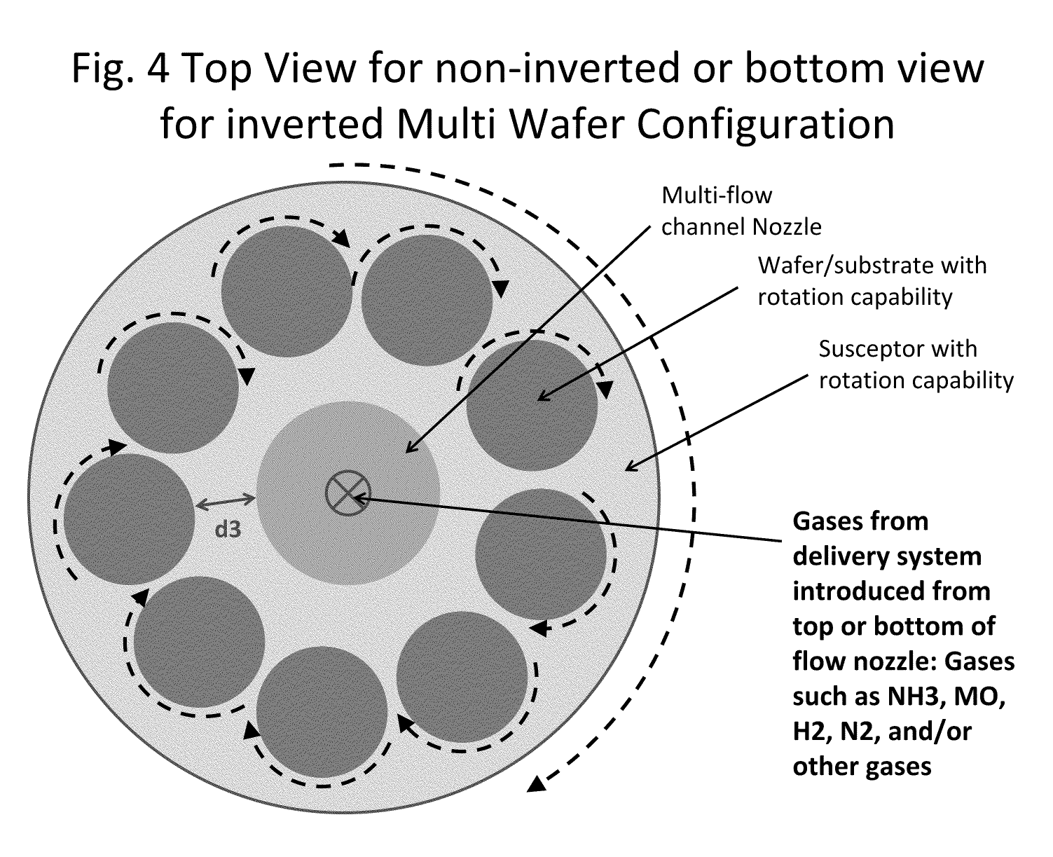

The horizontal chamber design can be configured for both single wafer reactors or for multi-wafer reactors. The wafer diameters in both configurations range from 2″ to 8″ or larger wafers, with the number of wafers in the multi-wafer configuration ranging from 2 to 60, depending on the diameter of the wafers and the chamber size. FIGS. 3 and 4 are schematic diagrams of a single wafer reactor and a multi-wafer reactor according to embodiments of the invention.

The flow nozzle accepts gases from the gas delivery systems and introduces the carrier gases (e.g., group III precursors, group V precursors, and dopant precursors) into the reaction chamber. Depending on the application, the gas delivery system (e.g., the nozzle shown in FIG. 3) is designed to introduce the gases to the nozzle horizontally or vertically. In a preferred multi-wafer embodiment, the gases are delivered vertically through the bottom of the nozzle such that there would be no gas delivery through the top of the growth chamber, leaving the tool easily accessible. The distance from the end of the flow nozzle to the leading edge of the wafer(s) ranges from about 1 mm to about 50 mm.

In one embodiment, the nozzle is constructed with only a single channel, and various types of gases are mixed in the nozzle before entering the growth chamber. In another embodiment, a nozzle with multi-flow channels is provided. The multi-flow channel design allows gases to be kept separate until they either freely interact in the chamber or interact at a predetermined mixing point such as at a mixing pin at the end of the nozzle. Another benefit to the separated flow channels is to strategically position the precursors relative to one another for more efficient growth and/or to mitigate pre-reactions. For example, the separated flow channels can be positioned side by side or stacked vertically. An example of the multi-flow channel nozzle with a vertically stacked configuration is shown in FIG. 1 and FIG. 2. In the vertically stacked configuration, it is desirable to flow an inert gas such as N2 through the flow channel closest to the tapered flow channel block to create a separation layer between the reactive precursors and the flow channel block. This helps prevent deposition on the flow channel block and forces the reactive gases even closer to the wafer surface where they are required for growth. The result is increased precursor utilization efficiency.

In some configurations, only the group V precursor such as NH3 is injected through the flow channel closest to the wafer surface. In other configurations, group III precursor and carrier gases are injected through this flow channel closest to the wafer surface. In other configurations, a combination of group V and group III precursors and carriers gases are injected through the flow channel closest to the wafer surface. For example, a vertically stacked flow channel design enables separation of some of the group III precursors from one another or from the NH3, which could be favorable due to the tendency for some precursors to pre-react with each other. For example, the aluminum precursor TMA1 could be introduced through a separate channel from the other precursors to prevent pre-reaction.

In a specific embodiment, the invention introduces the indium precursor TMIn or TEIn and carrier gas and optional group V precursor such as NH3 through the flow channel that is closest to the wafer surface. In such a configuration, the other group III precursors such as TEGa, TMGa, or TMA1 are through flow channels positioned further from the wafer surface. This configuration enables more efficient indium incorporation into the epitaxial film such as InGaN. The realization of high-quality, high-indium content InGaN is a known challenge in GaN based growth and such a configuration could be a great benefit.

The flow nozzle can be constructed from various types of materials, such as copper, alloyed copper, various grades of stainless steel, aluminum, or other. In a preferred embodiment the nozzle is copper.

In both the inverted or non-inverted design, the susceptor is configured to conducts heat from the heaters to the wafer. In various embodiments, the susceptor is configured to uniformly apply the heat to the wafers. In one embodiment, the susceptor is configured to rotate. Rotation can be achieved through an airfoil concept where flow gas propels the susceptor to rotate. In a specific embodiment, mechanical rotation means, such as gears, are provided to cause the susceptor to rotate. Susceptor rotation is illustrated in FIG. 3.

In the multi-wafer implementation, the susceptor can provide independent rotation of the entire susceptor containing all of the wafers and each individual wafer on the susceptor. For example, multiple-wave susceptor design with rotational means is illustrated in FIG. 4. Depending on the application, the susceptor could be can be made from graphite, SiC coated graphite, SiC, as well as other materials.

In various embodiments, heating of the susceptor and wafer is accomplished through resistive heaters or inductive heaters. In one embodiment, a heater is positioned on the opposite side of the susceptor from the wafer in the multi or single wafer reactor design. In another embodiment, the heater is positioned around the susceptor in the single wafer reactor design. The heater can have zones that could be independently controlled such that thermal gradients across the susceptor could be compensated. In one embodiment, the heater is controlled through feedback from a thermocouple. In another embodiment, the heater is designed to output a certain current/voltage in a resistive configuration.

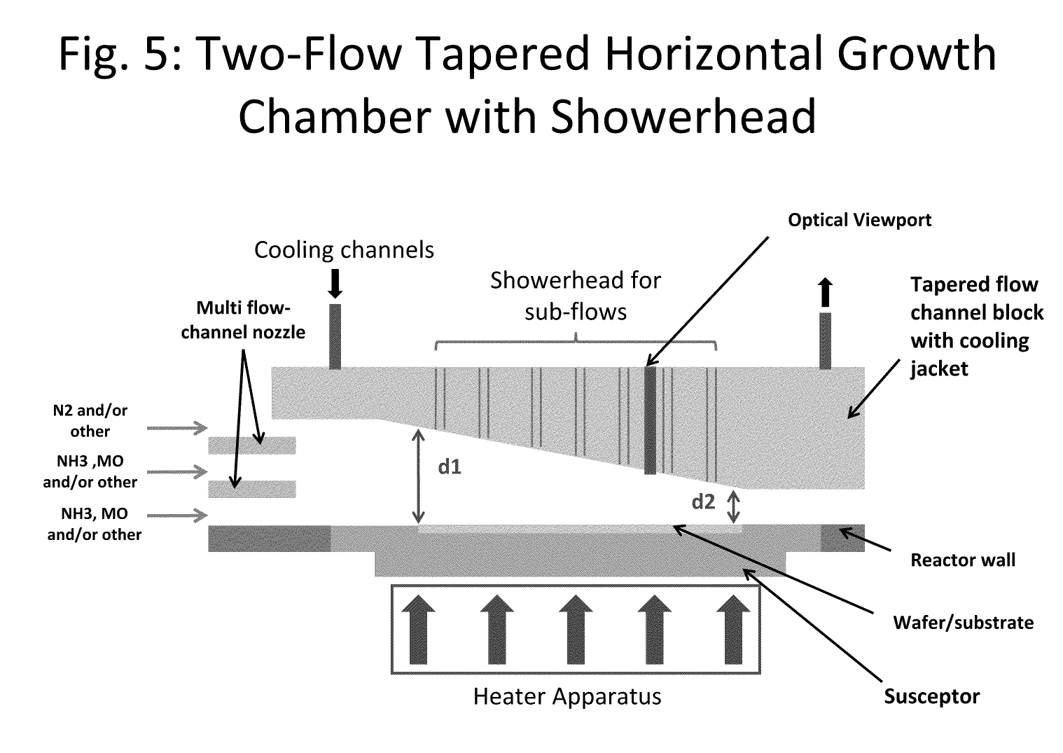

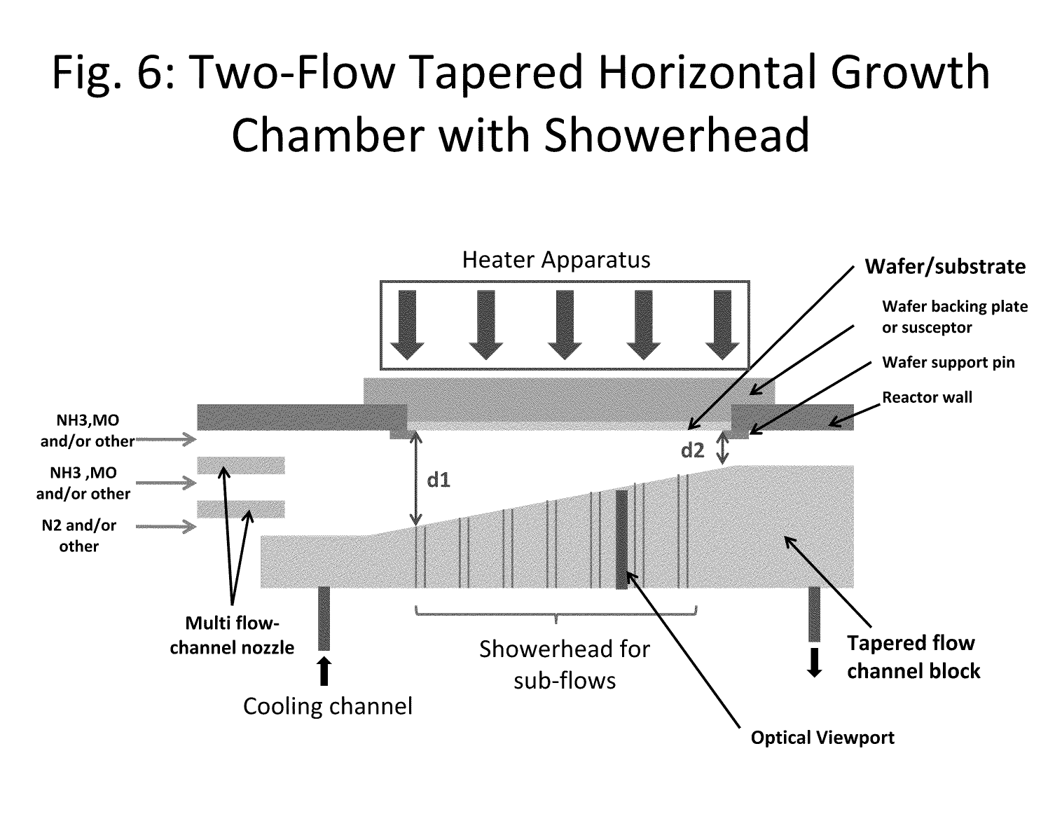

The tapered flow channel block may includes dispensing means, such as a showerhead assembly. For example, a two-flow assembly could be accomplished through a showerhead design within the tapered flow channel block. Sub-flow gas and/or carrier gas or MOs and NH₃ can be introduced into the reactor using the showerhead surface over the entire area of deposition. FIGS. 5 and 6 are diagrams illustrating tapered growth chambers with two-flow assemblies according to embodiments of the invention.

In various embodiments, a showerhead in the tapered growth chamber is water-cooled, although other coolants can be used. In one embodiment, the showerhead has a multiplicity of small tubes or vertical flow channels within the tapered water-cooled flow channel block, all the tubes or flow channels originating from the same place. The tubes or flow channels could be vertical or at an angle with the axis of the reactor. The showerhead flow or the subflow is to provide precise control of the boundary layer profile above the growth surface. The subflow changes the direction of the main flow to bring the reactants into contact with the substrate, which improves the uniformity of the film. In various embodiments, the showerhead assembly may also include optical viewport(s) for in-situ monitoring of growth rate, structural properties using x-ray, surface temperature monitoring using pyrometer, ellipsometry, curvature, etc.

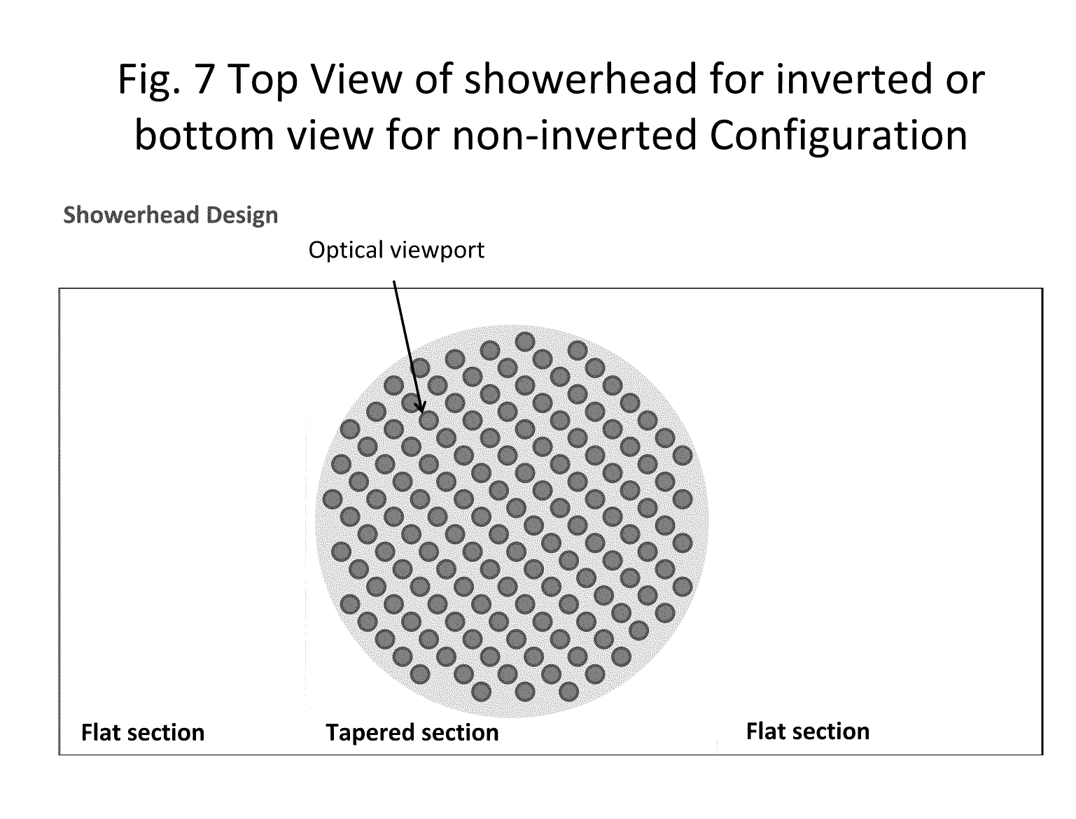

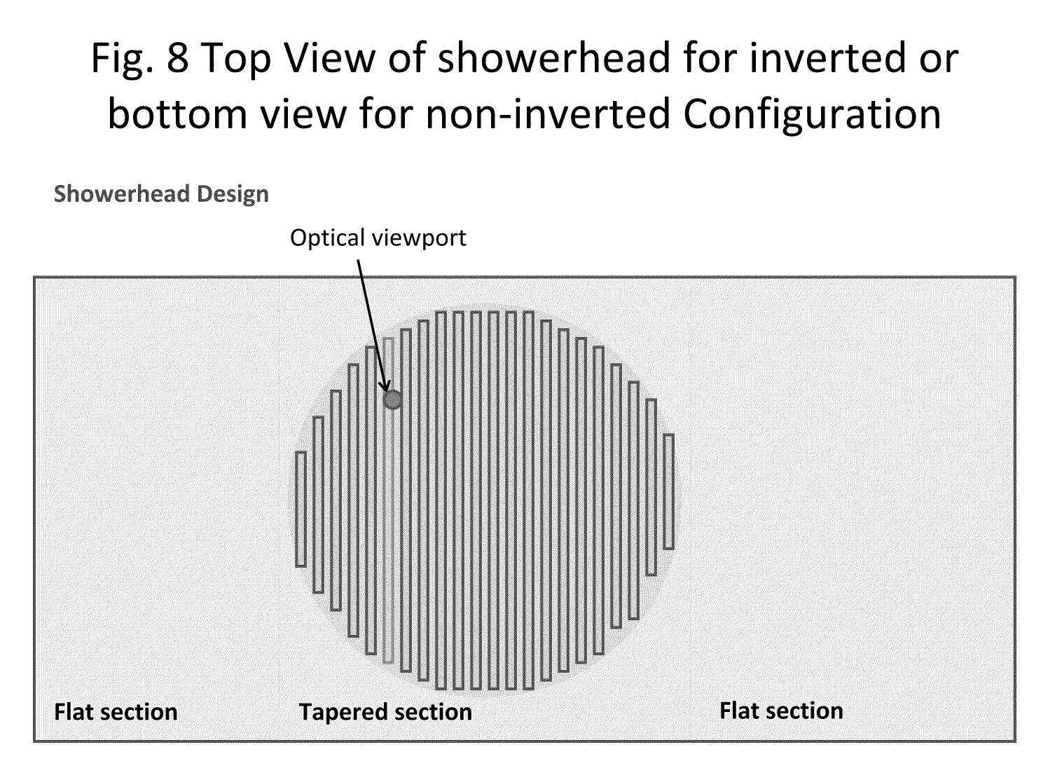

The showerhead tubes or flow channels can have different cross-sectional geometrical shapes, including cylindrical, cubical, trapezoidal, etc. The spacing between the tubes or flow channels could be adjusted based on the desired boundary layer profile and film uniformity. FIG. 7 is a top view of a showerhead with circuit flow channels according to an embodiment of the invention. FIG. 8 is a top view of a showerhead with rectangular flow channels.

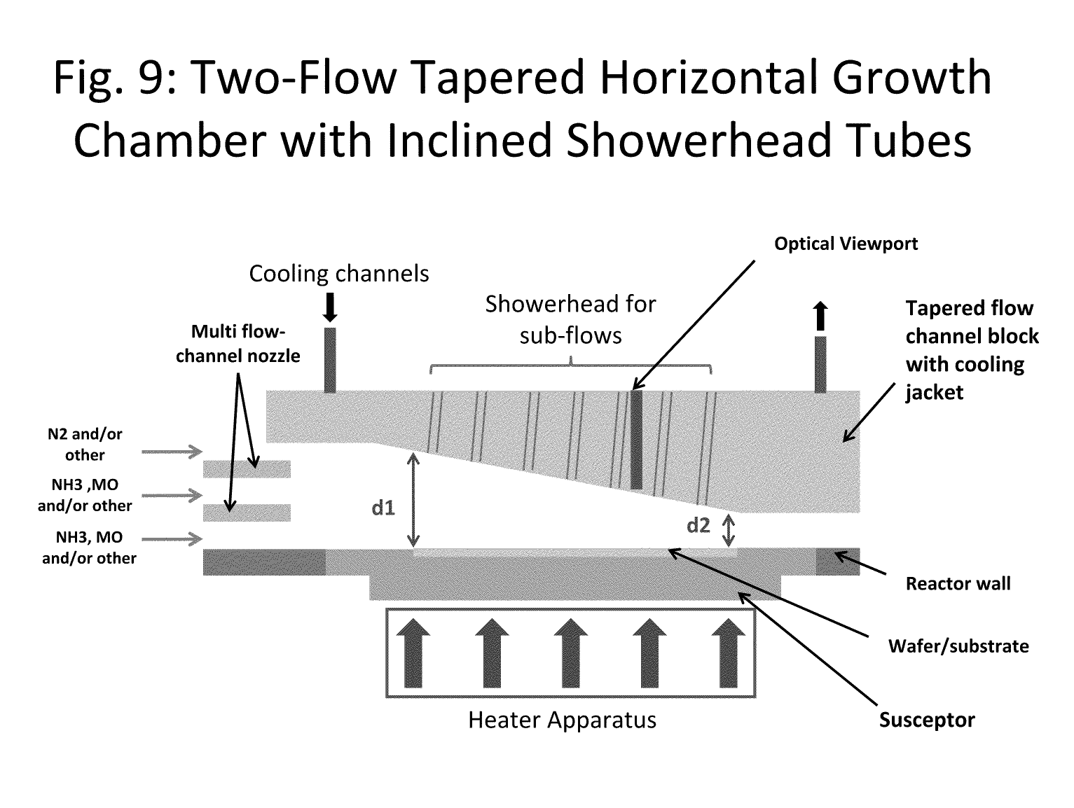

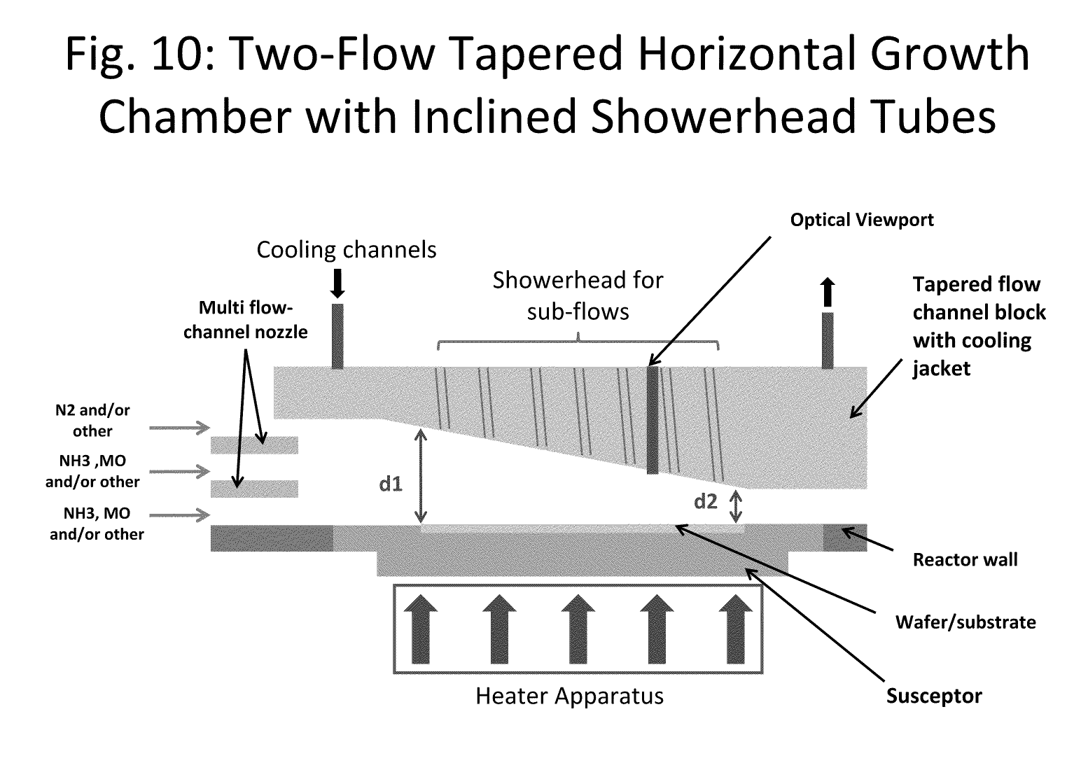

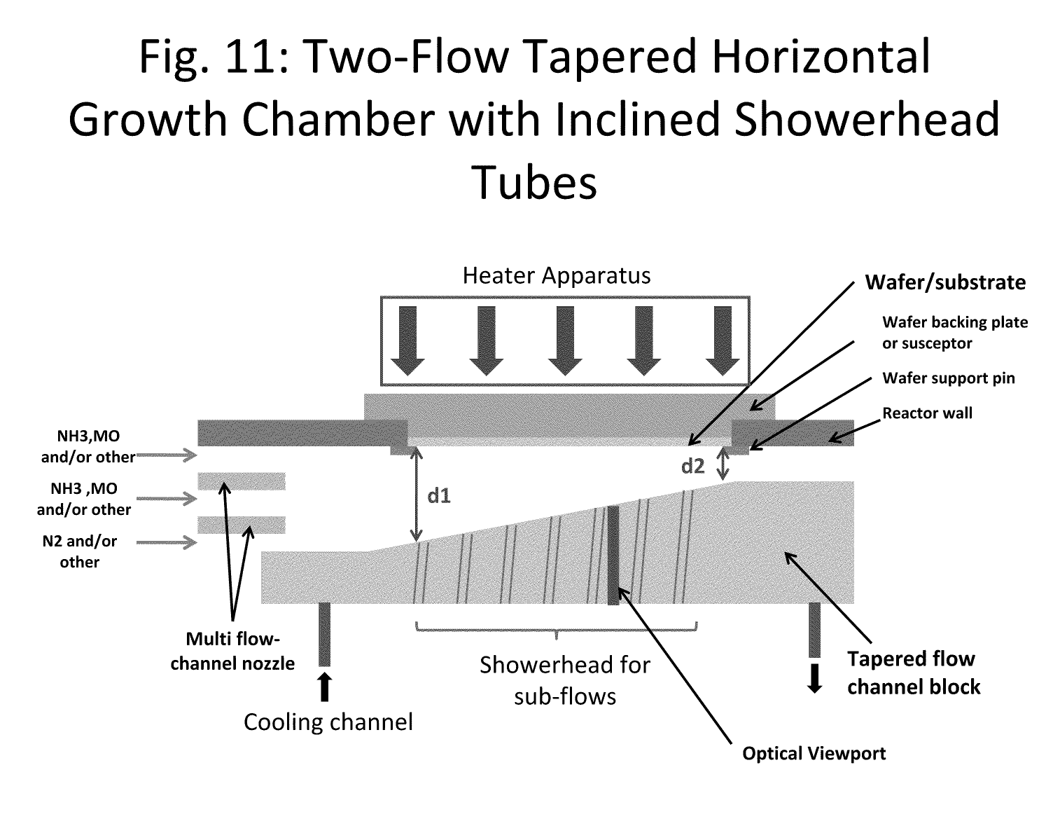

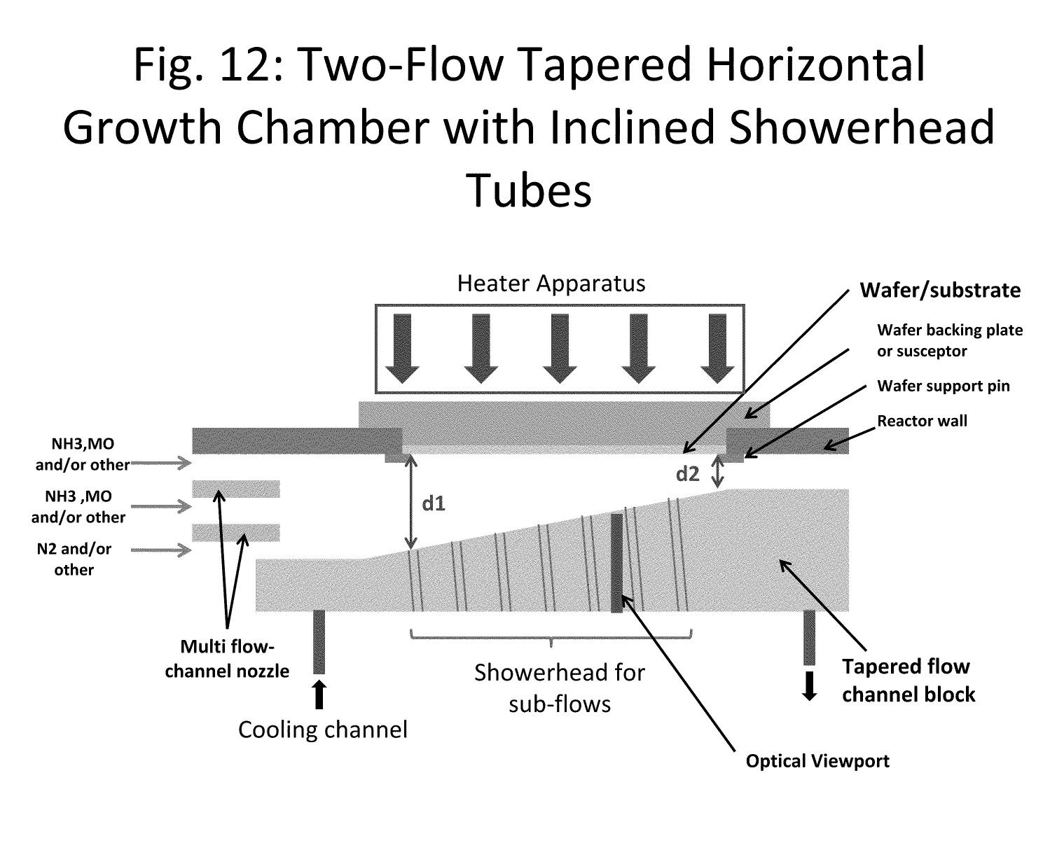

The showerhead may be configured in different angles. FIGS. 9-12 are simplified diagrams illustrating showerhead having tubes at different angles according to embodiments of the invention. While the above is a full description of the specific embodiments, various modifications, alternative constructions and equivalents may be used.

What is claimed is:

1. An MOCVD apparatus comprising:
an inlet region;
an outlet region;
a susceptor region between the inlet region and the outlet region; and
a flow region tapering from a first dimension at the inlet region to a second smaller dimension at the outlet region.

2. The apparatus of claim 1 further comprising a heater coupled to the susceptor region.

3. The apparatus of claim 1 further comprising cooling channels positioned near the flow region.

4. The apparatus of claim 1 wherein the inlet region includes cooling channels.

5. The apparatus of claim 1 further comprising a shower head dispenser configured to dispense into the flow region.

6. An apparatus for epitaxial growth comprising:
a reactor housing;
a susceptor having a holding surface for holding a wafer;
a tapered flow block, the tapered flow block having a tapered surface facing the holding surface;
a chamber formed between the holding surface and the tapered surface, the chamber being characterized a first height at a first end and a second height at a second end, the first height being defined by a first distance between the tapered surface and the holding surface at the first end, the second height being defined by a second distance between the tapered surface and the holding surface at the second end, the first height being greater than the second height by at least 20%;
a nozzle for introducing gaseous species into the chamber; and
a heating module thermally coupled to the susceptor.

7. The apparatus of claim 6 wherein the tapered flow block comprises metal and includes a showerhead assembly for dispensing cooling fluid.

8. The apparatus of claim 6 wherein the susceptor is capable of rotation.

9. The apparatus of claim 8 further comprising an airfoil positioned near the susceptor to cause the susceptor to rotate.

10. The apparatus of claim 6 wherein the nozzle comprises a plurality of vertically stacked flow channels.

11. The apparatus of claim 6 wherein the nozzle comprises a plurality of flow channels placed side-by-side.

12. The apparatus of claim 6 wherein the tapered surface is substantially flat.

13. The apparatus of claim 6 wherein the first height is at about 2 mm to 20 mm and the second height is about 0.5 mm to 5 mm.

14. The apparatus of claim 6 wherein the susceptor comprises a wafer backing plate configured to rotate at a predetermined rate.

15. The apparatus of claim 6 wherein the gaseous species comprise NH3, MO, H2, and N2.

16. The apparatus of claim 6 further comprising:
a shower head positioned within the tapered flow block and having a substantially circular shape and a plurality of circular flow channels; and
an optical viewport located on the shower head.

17. The apparatus of claim 16 wherein the susceptor is positioned below the tapered flow block.

18. The apparatus of claim 16 wherein the susceptor is positioned above the tapered flow block.

19. An apparatus for epitaxial growth comprising:
a reactor housing;
a susceptor having a holding surface for holding a wafer;
a tapered flow block having a tapered surface facing the holding surface;
a chamber between the holding surface and the tapered surface, the chamber being characterized a first height at a first end and a second height at a second end, the first height being defined by a first distance between the tapered surface and the holding surface at the first end, the second height being defined by a second distance between the tapered surface and the holding surface at the second end, the first height being different from the first height by at least 20%; and
a nozzle for introducing gaseous species into the chamber.

20. The apparatus of claim 19 further comprising a heating module positioned around the susceptor.
